(19) United States
(12) Patent Application Publication
(10) Pub. No.: US 2018/0102288 A1
(43) Pub. Date: Apr. 12, 2018

(54) WAFER PROCESSING METHOD

(71) Applicant: DISCO CORPORATION, Tokyo (JP)

(72) Inventor: Taewoo Bae, Tokyo (JP)

(21) Appl. No.: 15/725,842

(22) Filed: Oct. 5, 2017

(30) Foreign Application Priority Data
Oct. 11, 2016 (JP) 2016-200154

(51) Int. Cl. H01L 21/78; B23K 26/00; B23K 26/53

(52) U.S. Cl. CPC H01L 21/78; B23K 26/0006; B23K 2203/56; B23K 26/53; B23K 26/0063; B23K 26/0057

(57) ABSTRACT

A wafer processing method is provided. The wafer processing method includes a first laser processing step of forming a first modified layer inside the wafer by applying a laser beam at a wavelength which transmits the wafer along first projected division lines, a second laser processing step of forming a second modified layer inside the wafer excluding non-processed regions in intersecting regions where the first and second projected division lines intersect each other by applying a laser beam at a wavelength which transmits the wafer along the second projected division lines, and a grinding step of grinding a reverse side of the wafer to thin the wafer to a predetermined thickness and at the same time dividing the wafer into a plurality of chips starting from the first and second modified layers. In the second laser processing step, no second modified layers are formed in the non-processed regions.

### BACKGROUND OF THE INVENTION

### Field of the Invention

The present invention relates to a wafer processing method for modifying an inside of a wafer with a laser beam.

### Description of the Related Art

In electronic apparatus typical examples of which are mobile phones and personal computers, device chips with devices such as electronic circuits have become essential components. For example, areas of a face side of a wafer made of silicon or other semiconductor material are demarcated by a plurality of projected division lines (streets), after which devices are formed in the areas, and the wafer is divided along these projected division lines, thereby producing device chips.

There is known in the art a process called “stealth dicing (SD)” process, a process of dividing a wafer. According to the known process, a transmissive laser beam is focused within a wafer, thereby forming a modified layer (modified region) modified by multiphoton absorption. Reference may be made to Japanese Patent Laid-Open No. 2002-192370. The wafer can be divided starting from the modified layers by applying a force to the wafer after forming the modified layers along the projected division lines.

Incidentally, the SD process leads to modified layers remaining unremoved on the device chips being formed, often resulting in insufficiently enhanced flexural strength of the device chips. There is now provided a process called “stealth dicing before grinding (SDBG)” process, commercially available, for dividing a wafer into a plurality of device chips while removing modified layers by grinding a reverse side of the wafer after forming the modified layers. Reference may be made to PCT Patent Publication No. WO2003/077295.

### SUMMARY OF THE INVENTION

In the above SDBG, an additional step of dividing a wafer is not always necessary as the wafer is divided by the force applied during grinding. On the other hand, device chips have been prone to cracking and chipping as the corners of the device chips come into contact because of grinding which continues even after division into the device chips.

It is therefore an object of the present invention to provide a new wafer processing method so as to divide a wafer properly while keeping occurrences of cracking and chipping to a minimum.

In accordance with an aspect of the present invention, there is provided a wafer processing method of processing a wafer with a device disposed in each of areas demarcated by a plurality of first projected division lines that extend in a first direction and a plurality of second projected division lines that extend in a second direction intersecting the first direction. The wafer processing method includes a first laser processing step of forming a first modified layer inside the wafer by applying a laser beam at a wavelength which transmits the wafer along the first projected division lines, a second laser processing step of forming a second modified layer inside the wafer excluding non-processed regions in intersecting regions where the first and second projected division lines intersect each other by applying a laser beam at a wavelength which transmits the wafer along the second projected division lines, and a grinding step of grinding a reverse side of the wafer to thin the wafer to a predetermined thickness and at the same time dividing the wafer into a plurality of chips starting from the first and second modified layers after carrying out the first and second laser processing steps. In the second laser processing step, no second modified layers are formed in the non-processed regions.

In an embodiment of the present invention, the non-processed regions may preferably be sized 150 μm or more and 250 μm or less having their center at the centers of the first projected division lines along their width and extending in the second direction.

In the wafer processing method according to an embodiment of the present invention, it is possible to divide a wafer properly while keeping cracking and chipping to a minimum as no second modified layer is formed in non-processed regions provided in intersecting regions.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1A is a perspective view schematically depicting a configuration example of a wafer;

FIG. 1B is a perspective view schematically depicting the manner in which a protective member is applied to a wafer;

FIG. 2A is a partial sectional side view schematically depicting a first laser processing step;

FIG. 2B is a partial sectional side view schematically depicting a second laser processing step;

FIG. 3 is a view schematically depicting a wafer with first and second modified layers formed thereon; and

FIG. 4 is a partial sectional side view schematically depicting a grinding step.

### DETAILED DESCRIPTION OF THE PREFERRED EMBODIMENT

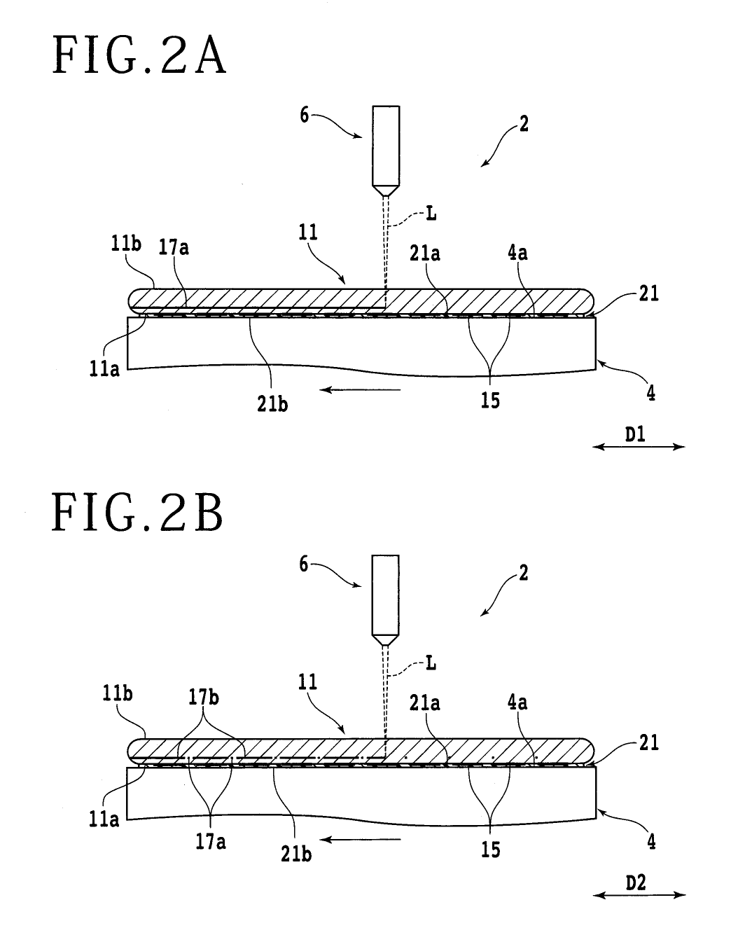

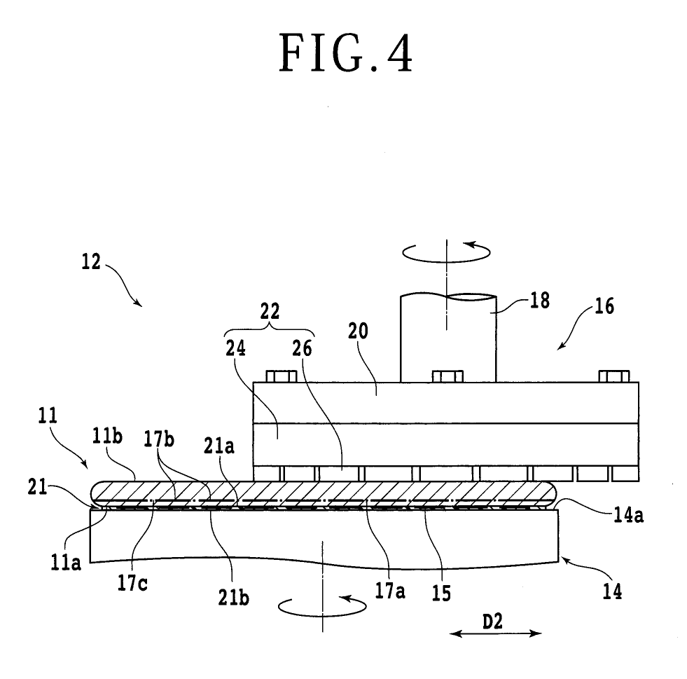

An embodiment according to an aspect of the present invention will be described with reference to the accompanying drawings. A wafer processing method according to the present embodiment includes a first laser processing step (see FIG. 2A), a second laser processing step (see FIG. 2B), and a grinding step (see FIG. 4). In the first laser processing step, a first modified layer is formed inside a wafer by applying a laser beam to the wafer along first projected division lines (first streets) that extend (stretch) in a first direction. In the second laser processing step, a second modified layer is formed inside the wafer excluding non-processed regions in intersecting regions where the first projected division lines and second projected division lines intersect each other by applying a laser beam to the wafer along the second projected division lines (second streets) that extend (stretch) in a second direction. In the grinding step, the wafer is thinned by grinding a reverse side thereof, and at the same time, divided into a plurality of chips (device chips). The wafer processing method according to the present embodiment will be described in detail below.

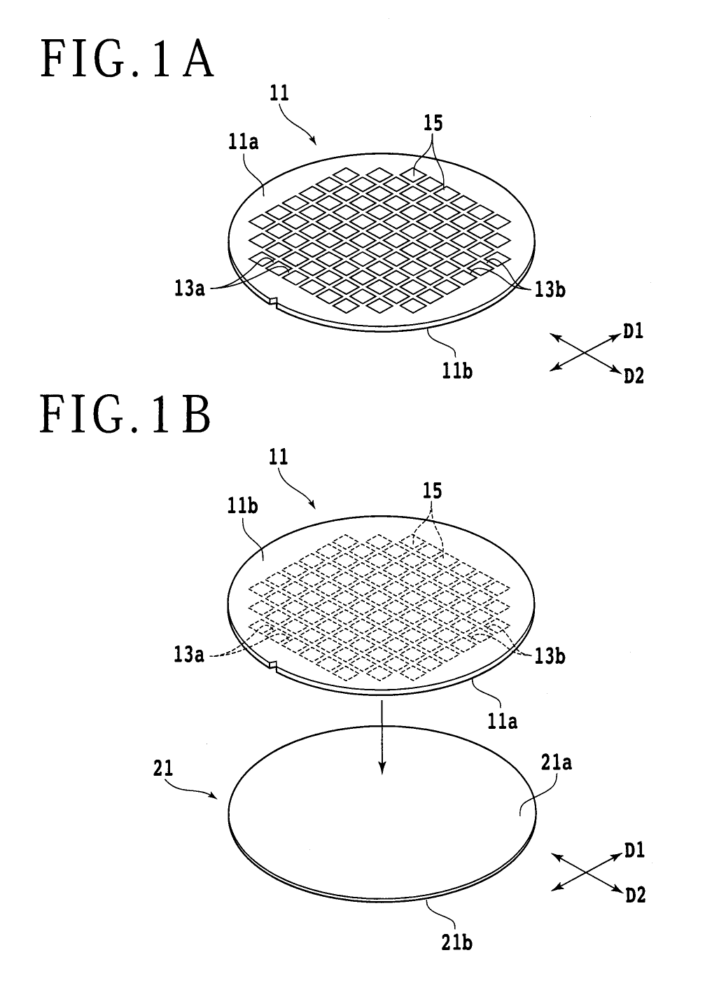

FIG. 1A is a perspective view schematically depicting a configuration example of a wafer. As depicted in FIG. 1A, a wafer 11 is formed into a disk shape using a semiconductor material such as silicon (Si). A face side 11a of the wafer 11 is demarcated into a plurality of areas by a plurality of first projected division lines (first streets) 13a that extend in a first direction D1 and a plurality of second projected division lines (second streets) 13b that extend in a second direction D2, with a device 15 such as integrated circuit (IC), large scale integration (LSI) or other device disposed in each area. In the present embodiment, the disk-shaped wafer 11 made of silicon or other semiconductor material is used. However, the wafer 11 has no limitation in material, shape, structure, size, or the like. For example, the wafer 11 made of ceramic or the like may be used. Similarly, the device 15 has no limitation in type, quantity, size, arrangement, and so on. The first direction D1 in which the first projected division lines 13a extend and the second direction D2 in which the second projected division lines 13b extend may intersect each other but may not need to be perpendicular to each other.

A protective member made of resin or the like is applied in advance to the face side 11a of the above wafer 11 before carrying out the wafer processing method according to the present embodiment. FIG. 1B is a perspective view schematically depicting the manner in which a protective member is applied to the wafer 11. A protective member 21 is, for example, circular film (tape) having the same diameter as the wafer 11, with an adhesive glue layer provided on a face side 21a thereof. As depicted in FIG. 1B, the protective member 21 may be applied to the face side 11a of the wafer 11 as the face side 21a of the protective member 21 is brought into close contact with the face side 11a of the wafer 11. Applying the protective member 21 to the face side 11a of the wafer 11 alleviates impact which will be exerted in each later step, thereby protecting the device 15 or the like provided on the face side 11a of the wafer 11.

After the protective member 21 is applied to the face side 11a of the wafer 11, a first laser processing step is carried out to apply a laser beam along the first projected division lines 13a, thereby forming a first modified layer inside the wafer 11. FIG. 2A is a partial sectional side view schematically depicting the first laser processing step. The first laser processing step is carried out, for example, by a laser processing apparatus 2 depicted in FIG. 2A. The laser processing apparatus 2 has a chuck table 4 for holding the wafer 11 under suction. The chuck table 4 is connected to a rotational drive source, not depicted, such as motor, rotating about a rotational axis approximately parallel to the vertical direction. A transfer mechanism, not depicted, is provided below the chuck table 4, causing the chuck table 4 to travel horizontally by this transfer mechanism. Part of a top side of the chuck table 4 serves as a holding surface 4a which holds the protective member 21 applied to the wafer 11 under suction. The holding surface 4a is connected to a suction source, not depicted, through a suction channel, not depicted, formed inside the chuck table 4 and so on. The wafer 11 is held on the chuck table 4 through the protective member 21 as a negative pressure is applied to the holding surface 4a from the suction source. A laser applying unit 6 is provided above the chuck table 4. The laser applying unit 6 applies a laser beam L which is generated by pulsed oscillation by a laser oscillator, not depicted, so that the laser beam L is focused at a predetermined position. The laser oscillator is arranged to generate the laser beam L at a wavelength which transmits the wafer 11, a wavelength which is not readily absorbed, by pulsed oscillation.

In the first laser processing step, a reverse side 21b of the protective member 21 that is applied to the wafer 11 is brought into contact with the holding surface 4a of the chuck table 4 first, and then a negative pressure is applied from the suction source. As a result, the wafer 11 is held on the chuck table 4 with a reverse side 11b of the wafer 11 exposed upwardly. Next, the chuck table 4 is transferred and rotated, for example, so that the laser applying unit 6 lies on the line extending from the target first projected division line 13a. Then as depicted in FIG. 2A, the chuck table 4 is transferred in the direction parallel to the target first projected division line 13a while the laser beam L is applied to the reverse side 11b of the wafer 11 from the laser applying unit 6. The laser beam L is focused at a predetermined depth inside the wafer 11. As the laser beam L at a wavelength that transmits (penetrates) the wafer 11 is focused inside the wafer 11, the inside of the wafer 11 is modified, thereby forming a first modified layer 17a, a starting point of division.

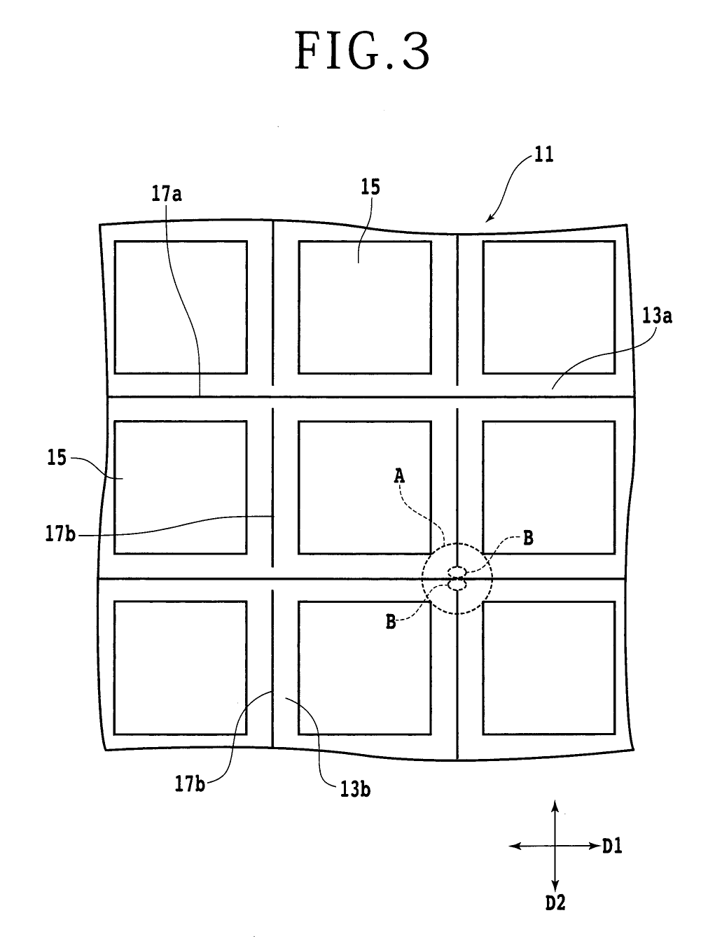

Preferably, the first modified layer 17 a may be formed at a depth where the layer will be removed by later grinding. For example, if the wafer 11 is thinned to a thickness of approximately 30 μm by grinding the reverse side 11b of the wafer 11, the first modified layers 17a may be formed at a depth of approximately 70 μm from the face side 11a. The first modified layers 17a are also formed in intersecting regions A (see FIG. 3) where the first projected division lines 13a and the second projected division lines 13b intersect each other in a continuous and integrated manner. The first laser processing step comes to an end when the first modified layers 17a are formed along all the first projected division lines 13a as a result of repetition of the above operation. Preferably, the first modified layers 17a are formed on condition that cracks reach the face side 11a. The plurality of first modified layers 17a may be formed at different depths relative to each of the first projected division lines 13a.

After the first laser processing step, a second laser processing step is carried out to apply the laser beam L to the wafer along the second projected division lines 13b, thereby forming a second modified layer inside the wafer 11. FIG. 2B is a partial sectional side view schematically depicting the second laser processing step. The second laser processing step is also carried out by the laser processing apparatus 2.

In the second laser processing step, the chuck table 4 is transferred and rotated first, for example, so that the laser applying unit 6 lies on the line extending from the target second projected division line 13b. Then as depicted in FIG. 2B, the chuck table 4 is transferred in the direction parallel to the target second projected division line 13b while the laser beam L is applied to the reverse side 11b of the wafer 11 from the laser applying unit 6. The laser beam L is focused at a predetermined depth inside the wafer 11. The inside of the wafer 11 is modified, thereby forming a second modified layer 17b, a starting point of division. Preferably, the second modified layer 17b is formed at the same depth as the first modified layer 17a. Preferably, the second modified layers 17b are formed on condition that cracks reach the face side 11a.

In the second laser processing step, the second modified layers 17b are not formed in part of the intersecting regions A where the first projected division lines 13a and the second projected division lines 13b intersect each other. FIG. 3 is a view schematically depicting the wafer 11 with the first modified layers 17a and the second modified layers 17b formed thereon. In FIG. 3, not only the devices 15 formed on the face side 11a of the wafer 11 but also the first modified layers 17a and the second modified layers 17b are depicted by solid lines for convenience of description. As depicted in FIG. 3, the second modified layers 17b are formed inside the wafer 11 excluding non-processed regions B in the intersecting regions A where the first projected division lines 13a and the second projected division lines 13b intersect each other. That is, in the second laser processing step, the non-continuous and discrete second modified layers 17b, divided by the non-processed regions B, are formed. The non-processed regions B may have any size and be arranged in any way. Preferably, for example, the non-processed regions B are 150 μm or more and 250 μm or less in length having their centers at the centers of the first projected division lines 13a along their widths and extending in the second direction D2. More preferably, the non-processed regions B are approximately 200 μm in length. In this case, the non-processed regions B are arranged roughly symmetrically relative to the first modified layers 17a.

Since no second modified layers 17b are formed in the non-processed regions B of the intersecting regions A as described above, the wafer 11 can be ground without dividing it in the early stage of grinding carried out later, which means that the wafer can be ground while chips remain connected by the non-processed regions B. Therefore, it is less likely that cracking and chipping will occur as a result of the corners of the device chips divided from the wafer 11 coming into contact with each other in the intersecting regions A. When the second modified layers 17b are formed along all the second projected division lines 13b after the above operation is repeated, the second laser processing step comes to an end. In the second laser processing step, the plurality of second modified layers 17b may be similarly formed at different depths relative to each of the second projected division lines 13b. The first laser processing step may be carried out after the second laser processing step rather than carrying out the second laser processing step after the first laser processing step as done in the present embodiment.

Following the first and second laser processing steps, a grinding step is carried out to thin the wafer 11 by grinding the reverse side 11b thereof and to divide the wafer 11 into a plurality of chips. FIG. 4 is a partial sectional side view schematically depicting the grinding step. The grinding step is carried out, for example, by a grinding apparatus 12 depicted in FIG. 4. The grinding apparatus 12 has a chuck table 14 for holding the wafer 11 under suction. The chuck table 14 is connected to a rotational drive source, not depicted, such as motor, rotating about a rotational axis approximately parallel to the vertical direction. A transfer mechanism, not depicted, is provided below the chuck table 14, causing the chuck table 14 to travel horizontally by this transfer mechanism. Part of a top side of the chuck table 14 serves as a holding surface 14a which holds the protective member 21 applied to the wafer 11 under suction. The holding surface 14a is connected to a suction source, not depicted, through a suction channel, not depicted, formed inside the chuck table 14 and so on. The wafer 11 is held on the chuck table 14 through the protective member 21 as a negative pressure is applied to the holding surface 14a from the suction source.

A grinding unit 16 is provided above the chuck table 14. The grinding unit 16 has a spindle housing, not depicted, which is supported by an elevating mechanism, not depicted. A spindle 18 is accommodated in the spindle housing, and a disk-shaped mount 20 is secured to a lower end of the spindle 18. A grinding wheel 22 of approximately the same diameter as the mount 20 is attached to a bottom side of the mount 20. The grinding wheel 22 has a wheel base 24 that is formed from a metallic material such as stainless steel or aluminum. A plurality of grinding stones 26 are disposed on a bottom face of the wheel base 24 in an annular manner. A rotational drive source, not depicted, such as motor, is connected to a top end (base end) of the spindle 18, causing the grinding wheel 22 to rotate about a rotational axis approximately parallel to the vertical direction by the force produced by the rotational drive source. A nozzle, not depicted, is provided inside or near the grinding unit 16 to supply a grinding liquid such as purified water to the wafer 11 or the like.

In the grinding step, the wafer 11 unloaded from the chuck table 4 of the laser processing apparatus 2 is held under suction by the chuck table 14 of the grinding apparatus 12 first. Specifically, the reverse side 21b of the protective member 21 that is applied to the wafer 11 is brought into contact with the holding surface 14a of the chuck table 4 first, and then a negative pressure is applied from the suction source. As a result, the wafer 11 is held on the chuck table 14 with the reverse side 11b of the wafer 11 exposed upwardly. Next, the chuck table 14 is moved under the grinding unit 16. Then as depicted in FIG. 4, the chuck table 14 and the grinding wheel 22 are each rotated, and the spindle housing including the spindle 18 and the grinding wheel 22 is lowered while a grinding liquid is supplied to the reverse side 11b of the wafer 11 or the like. The lowering speed (descent) of the spindle housing is adjusted to such an extent that the bottom sides of the grinding stones 26 are pressed against the reverse side 11b of the wafer 11. As a result, the wafer 11 can be thinned by grinding the reverse side 11b of the wafer 11. The grinding step comes to an end when the wafer 11 is thinned to a predetermined finished thickness, after which the wafer is divided into a plurality of chips starting, for example, from the first modified layers 17a and the second modified layers 17b.

The reverse side 11b of the wafer 11 may be ground by two or more grinding units including two or more sets of grinding stones rather than by the single grinding unit 16 including a single set of grinding stones as done in the present embodiment. For example, the flatness of the reverse side 11b can be improved without significantly increasing the time required for grinding by carrying out coarse grinding using grinding stones having abrasive grains of large diameter followed by finished grinding using grinding stones having abrasive grains of small diameter.

Next, an experiment carried out to verify the effects of the wafer processing method according to the present embodiment will be described. In the present experiment, wafers were processed under a plurality of conditions in which the above non-processed regions B were different in length, and the numbers of occurrences of cracking and chipping which means the numbers of areas where cracking or chipping was found were verified in each condition. Two types of wafers, one being a “0 degree wafer” having projected division lines along the crystal orientation while the other being a “45 degree wafer” having projected division lines that tilt at an angle of 45 degrees relative to the crystal orientation, were used. In the present experiment, the non-processed regions B had their centers at the centers of the first projected division lines along their widths and extended in the second direction so that the non-processed regions B were symmetrical relative to the first modified layers. The result of the experiment is depicted in Table 1.

TABLE 1

| Length of | Number of | Number of |
|---|---|---|
| Non-Processed Region | Cracks/Chips in 0 | Cracks/Chips in 45 |
| (μm) | Degree Wafer | Degree Wafer |
| 100 | 11 | 15 |
| 150 | 7 | 14 |
| 200 | 5 | 14 |
| 250 | 8 | 14 |
| 300 | 16 | 20 |

It is understandable that if the non-processed regions B are 150 μm or more and 250 μm or less in length having their centers at the centers of the first projected division lines along their widths and extending in the second direction, both the “0 degree wafers” and the “45 degree wafers” have lesser numbers of cracks and chips. The wafers with the 200 μm-long non-processed regions B show particularly excellent results.

For reference reasons, another experiment was carried out using wafers having the 200 μm-long non-processed regions B extending in the first direction and the 200 μm-long non-processed regions B extending in the second direction. In this case, 18 cracks and chips were found in the “0 degree wafer,” and 17 were found in the “45 degree wafer.” Hence, the non-processed regions B preferably extend only either in the second or first direction.

As described above, no second modified layers 17b are formed in the non-processed regions B having a given length that are provided in the intersecting regions A in the wafer processing method according to the present embodiment. As a result, the wafer 11 can be divided properly while keeping occurrences of cracking and chipping to a minimum.

The present invention is not limited to the details of the above embodiment but can be carried out in various modified manners. For example, in the above embodiment, non-processed regions extend in the second direction in the intersecting regions where the first and second projected division lines intersect each other, and non-continuous and discrete second modified layers are formed by the second laser processing step. However, the distinction between the first and second directions, between the first and second projected division lines, and between the first and second modified layers are all given for the sake of convenience, and the relationships therebetween may be changed. For example, non-processed regions may extend in the first direction in the intersecting regions where the first and second projected division lines intersect each other, and non-continuous and discrete first modified layers may be formed by the first laser processing step.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A wafer processing method of processing a wafer with a device disposed in each of areas of a face side demarcated by a plurality of first projected division lines that extend in a first direction and a plurality of second projected division lines that extend in a second direction intersecting the first direction, the wafer processing method comprising:
a first laser processing step of forming a first modified layer inside the wafer by applying a laser beam at a wavelength which transmits the wafer along the first projected division lines;
a second laser processing step of forming a second modified layer inside the wafer excluding non-processed regions in intersecting regions where the first and second projected division lines intersect each other by applying a laser beam at a wavelength which transmits the wafer along the second projected division lines; and
a grinding step of grinding a reverse side of the wafer to thin the wafer to a predetermined thickness and at the same time dividing the wafer into a plurality of chips starting from the first and second modified layers after carrying out the first and second laser processing steps, wherein
in the second laser processing step, no second modified layers are formed in the non-processed regions.

2. The wafer processing method of claim 1, wherein the non-processed region is sized 150 μm or more and 250 μm or less having its center at the center of the first projected division line along its width and extending in the second direction.
